(19) United States
(12) Patent Application Publication
(10) Pub. No.: US 2016/0315264 A1
(43) Pub. Date: Oct. 27, 2016

(54) Flexible Display and Method for Manufacturing a Multi-Layer Structure

(71) Applicant: EverDisplay Optronics (Shanghai) Limited, Shanghai (CN)

(72) Inventors: PingI Shih, Shanghai (CN); Mingyue Zhang, Shanghai (CN)

(73) Assignee: EverDisplay Optronics (Shanghai) Limited

(21) Appl. No.: 15/135,126

(22) Filed: Apr. 21, 2016

(30) Foreign Application Priority Data
Apr. 23, 2015 (CN) 201510199037.6

(51) Int. Cl. H01L 51/00; H01L 51/52; H01L 51/56

(52) U.S. Cl. CPC H01L 51/0024; H01L 51/56; H01L 51/524; H01L 2251/5338

(57) ABSTRACT

A method for manufacturing a multi-layer structure includes providing a first film with a silicon-based material layer thereon; providing a second film with the silicon-based material layer thereon; pre-treating the silicon-based material layer on each of the first and second film with an ion beam; and attaching the first film to the second film through the silicon-based material layer, such that the silicon-based materials layer on the first and second film are disposed between the first film and the second film to form the multi layers structure.

### CROSS-REFERENCE TO RELATED INVENTIONS

The present invention claims priority to and the benefit of Chinese Patent invention No. CN 201510199037.6, filed on Apr. 23, 2015, the entire content of which is incorporated herein by reference.

### BACKGROUND OF THE INVENTION

The present invention relates to a method for producing a flexible display device and, more particularly, to a flexible display.

Organic light emitting diode (OLED) devices have become the most potential novel display devices due to the advantages of the full solid state, self-illumination, free of backlight sources, low driving voltage, high efficiency, thin structure, and flexible display. Using a flexible substrate to make a flexible, lightweight, easy-to-carry flexible display device is the important developing direction of OLED devices. Since the electrode materials and the emissive materials of the OLED devices are sensitive to oxygen and water vapor, existence of oxygen and water vapor in the devices is the main factor of the life of the devices. Thus, using a proper packaging substrate and a proper packaging method to protect an OLED device from being affected by ambient environmental factors has a significant meaning in improving the efficiency and life of the devices.

FIG. 1 shows a conventional flexible OLED display device comprised of a plurality of flexible films bonded to each other. The flexible OLED display device includes a hard coating 10, a touch film 11, a polarizer 12, a flexible cover 13, and a flexible substrate 14 bearing an OLED device. During production of the OLED display device, an adhesive 15 is used to bond the above films to form a flexible OLED display device.

However, continuous flexing of the flexible OLED display device during use could cause failure of the adhesive 15, such that the films constituting the flexible OLED display device could peel off. Furthermore, a portion of the adhesive 15 in the flexible OLED display device could fail after having been used for a long period of time, such that the water vapor and oxygen enter an interior of the flexible OLED display device via a side of the flexible OLED display device, causing malfunction of the flexible OLED display device.

### BRIEF SUMMARY OF THE INVENTION

In according to one aspect of the disclosure, the advantages of the present embodiment include the followings: the method for manufacturing a multi-layer structure, comprising the steps of: comprise the step of:

providing a first film with a silicon-based material layer thereon;

providing a second film with the silicon-based material layer thereon;

pre-treating the silicon-based material layer on each of the first and second film with an ion beam; and

attaching the first film to the second film through the silicon-based material layer, such that the silicon-based material layers on the first and second film are disposed between the first film and the second film to form the multi layers structure.

Another objective of the present disclosure is that the silicon-based material layer is made of SiNx or SiOx.

Another objective of the present disclosure is that the silicon-based material layer is formed by evaporation or magnetron sputtering.

Another objective of the present disclosure is that the ion beam is an argon ion beam.

Another objective of the present disclosure is that the first film includes at least one of a flexible substrate, a display device layer, a flexible cover, a polarizer, and a touch film.

Still, another objective of the present disclosure is that the second film includes at least one of a flexible substrate, a display device layer, a flexible cover, a polarizer, and a touch film.

Still, another objective of the present disclosure is that the display device layer includes an organic light emitting diode and a thin film transistor for driving the organic light emitting diode.

Still, another objective of the present disclosure is that the display device layer includes an organic light emitting diode and a thin film transistor for driving the organic light emitting diode.

Still, it is another objective of the present disclosure that a flexible display comprising a first film and a second film; and the first film and the second film are attached by a silicon-based material layer.

Still, another objective of the present disclosure is that the silicon-based material layer is made of SiNx or SiOx.

Still, another objective of the present disclosure is that the first film includes at least one of a flexible substrate, a display device layer, a flexible cover, a polarizer, and a touch film.

Still, another objective of the present disclosure is that the second film includes at least one of a flexible substrate, a display device layer, a flexible cover, a polarizer, and a touch film.

Still, another objective of the present disclosure is that the display device layer includes an organic light emitting diode and a thin film transistor for driving the organic light emitting diode.

The present invention will become clearer in light of the following detailed description of illustrative embodiments of this invention described in connection with the drawings.

### DESCRIPTION OF THE DRAWINGS

FIG. 1 is a diagrammatic cross sectional view of a conventional flexible OLED display device.

FIG. 2 is a diagrammatic view illustrating preparation of silicon-based first and second films of a method for manufacturing a multi layers structure according to the present invention.

FIG. 3 is a diagrammatic view illustrating a resultant structure of first and second films of FIG. 2.

FIG. 4 is a diagrammatic view of a flexible display produced by the method for a flexible display according to the present invention.

FIG. 5 is a diagrammatic view illustrating an example of bonding of the first and second flexible films of the method for manufacturing a flexible display according to the present invention.

FIG. 6 is a diagrammatic view illustrating the resultant structure after bonding of the first and second flexible films of FIG. 5.

FIG. 7 is a diagrammatic view illustrating bonding of third and fourth flexible films of the packaging method for a flexible display according to the present invention.

FIG. 8 is a diagrammatic view illustrating the resultant structure after bonding of the third and fourth flexible films of FIG. 7.

FIG. 9 is a diagrammatic view illustrating bonding of fifth and sixth flexible films of the packaging method for a flexible display according to the present invention.

FIG. 10 is a diagrammatic view illustrating the resultant structure after bonding of the fifth and sixth flexible films of FIG. 9.

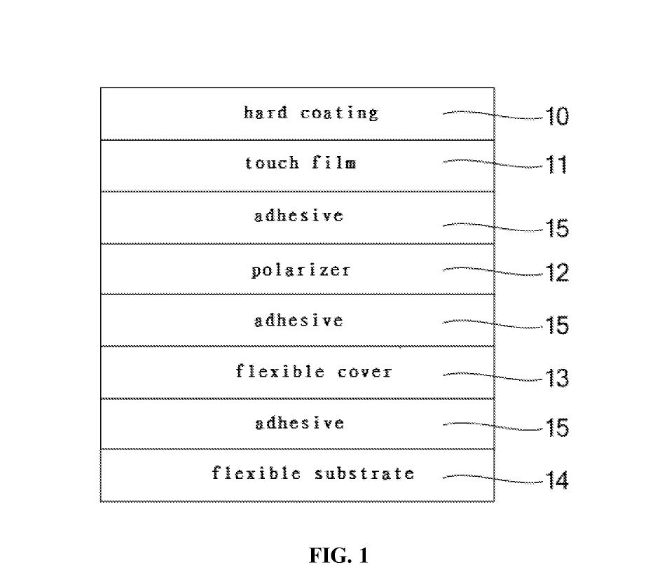

### DETAILED DESCRIPTION OF THE INVENTION

A method for manufacturing a multi-layer structure according to the present invention will now be set forth in connection with the accompanying drawings.

The method for manufacturing a multi-layer structure according to the present invention uses a silicon-based material to bond flexible films together.

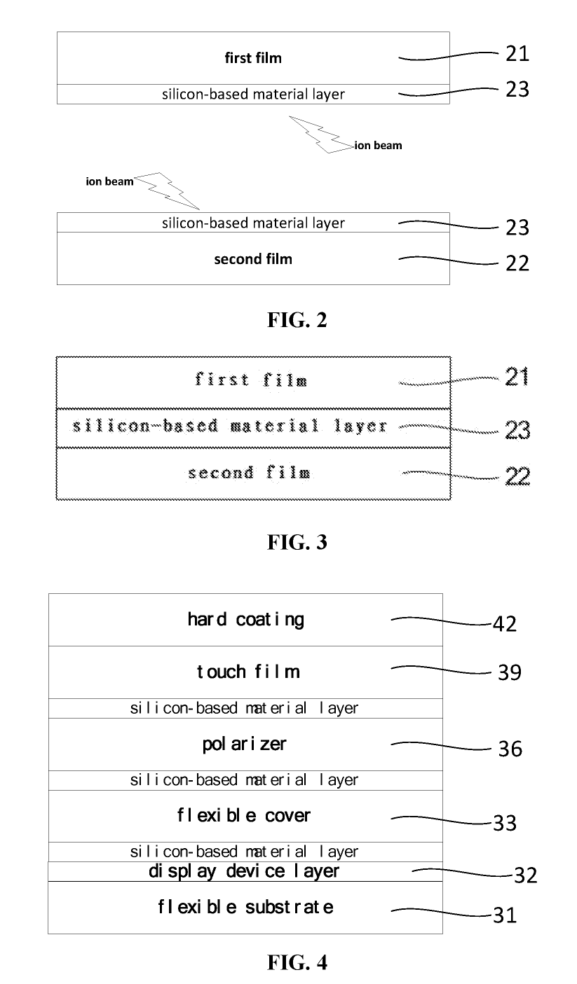

With reference to FIG. 2, the method for manufacturing a multi-layer structure includes providing a first film 21 with a silicon-based material layer 23 thereon(by evaporation or magnetron sputtering) and a second film 22 with a silicon-based material layer 23 thereon. Pre-treating the silicon-based material layer 23 on each of the first film 21 and the second film 22 with an ion beam, then attaching the first film 21 to the second film 22 through the silicon-based material layer 23, such that the silicon-based material layer 23 on the first and second film are disposed between the first film 21 and the second film 22 to form the multi layers structure.

In this embodiment, the silicon-based material layer 23 is made of SiNₓ or SiOₓ.

After formation of the silicon-based material layers 23, an ion beam is used to process the silicon-based material layer 23 on each of the first and second films 21 and 22. In the processing by the ion beam, argon (Ar) is filled into a vacuum chamber. When the gas pressure reaches a predetermined value and the voltage gradient is suitable, a glow discharge occurs between the evaporation source and the substrate, such that the argon ions are accelerated to fly towards the silicon-based material layer 23. Under the bombing by the argon ions, the ionic bonds of the silicon-based material on the surface of the silicon-based material layer 23 break.

With reference to FIG. 3, after ionic bombing on the silicon-based material layers 23, the silicon-based material layer 23 on the firs film 21 is engaged with the silicon-based material layer 23 on the second film 22. Since the ionic bonds of the silicon based materials on the silicon-based material layers 23 break, the silicon-based materials on the first and second films 21 and 22 grow new ionic bonds to bond the first and second films 21 and 22 together. The first film and the second film is preferably a flexible film.

With reference to FIG. 4, the flexible display formed by the packaging method according to the present invention includes a flexible substrate 31, a display device layer 32, a flexible cover 33, a polarizer 36, and a touch film 39, all of which are flexible films. Note that the first flexible film 21 can include at least one of the flexible substrate 31, the display device layer 32, the flexible cover 33, the polarizer 36, and the touch film 39. In a case that the first flexible film 21 includes two or more of the above films, the films are stacked in sequence to form a laminated film.

The second flexible film 22 includes at least one of a flexible substrate 31, a display device layer 32, a flexible cover 33, a polarizer 36, and a touch film 39. In a case that the second flexible film 22 includes two or more of the above films, the films are stacked in sequence to form a laminated film.

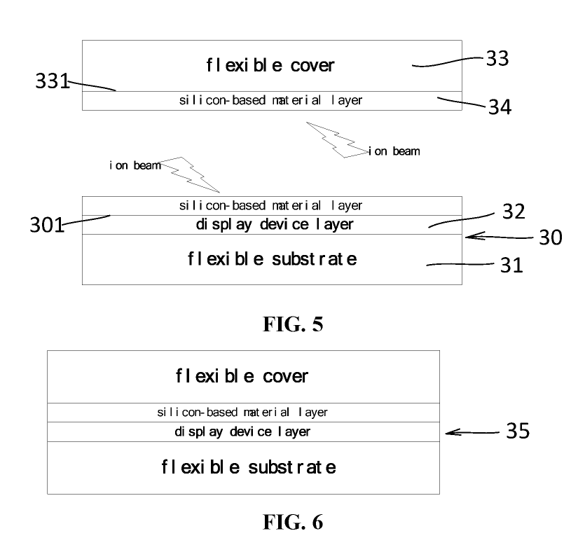

In an example, the second flexible film (a flexible cover 33) is bonded to the first flexible film 30 to form a third flexible film 35. As shown in FIG. 5, in this embodiment, the first flexible film 30 includes a flexible substrate 31 and a display device layer 32 disposed on an upper face of the flexible substrate 31. The display device layer 32 includes an organic light emitting diode and a thin film transistor for driving the organic light emitting diode. An upper face of the display device layer 32 of the first flexible film 30 serves as a first packaging face 301. In this embodiment, the second flexible film is a flexible cover 33 having a lower face serving as a second packaging face 331.

Specifically, with reference to FIGS. 5 and 6, in the bonding process, a silicon-based material layer 34 is disposed on each of the first face 301 and the second face 331. Then, the silicon-based material layers 34 of the first face 301 and the second face 331 are shot with ion beams to bond the first face 301 and the second face 331 together, such that the silicon-based material layers 34 of the first packaging face 301 and the second packaging face 331 engage with each other. After engagement of the silicon-based material layers 34 of the first face 301 and the second face 331, the second flexible film (the flexible cover 33) is bonded to the first flexible film 30 to form the third flexible film 35.

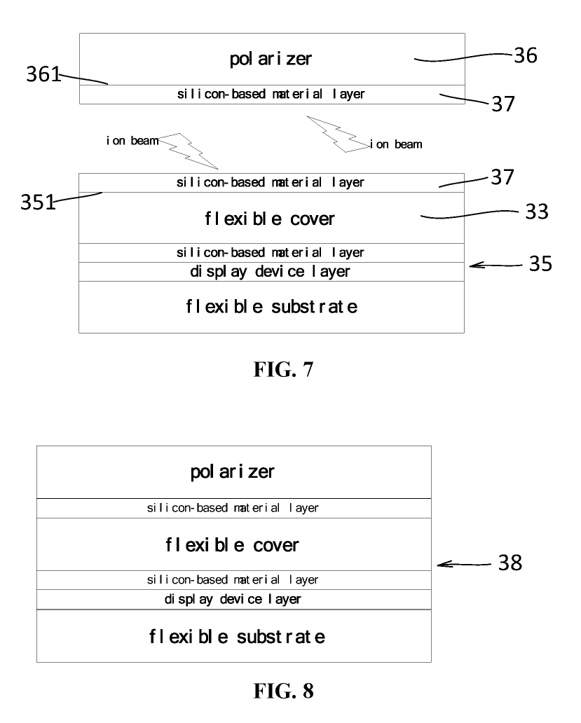

A fourth flexible film (the polarizer 36) is bonded to the third flexible film 35 to form a fifth flexible film 38. As shown in FIG. 7, in this embodiment, the fourth flexible film is a polarizer 36. A lower face of the polarizer 36 serves as a fourth face 361. An upper face of the flexible cover 33 of the third flexible film 35 serves as a third face 351.

Specifically, with reference to FIGS. 7 and 8, in the bonding process, a silicon-based material layer 37 is disposed on each of the third face 351 and the fourth face 361. Then, the silicon-based material layers 37 of the third face 351 and the fourth face 361 are shot with ion beams to bond the third face 351 and the fourth face 361 together, such that the silicon-based material layers 37 of the third face 351 and the fourth face 361 engage with each other. After engagement of the silicon-based material layers 37 of the third face 351 and the fourth face 361, the fourth flexible film (the polarizer 361 is bonded to the third flexible film 35 to form the fifth third flexible film 38.

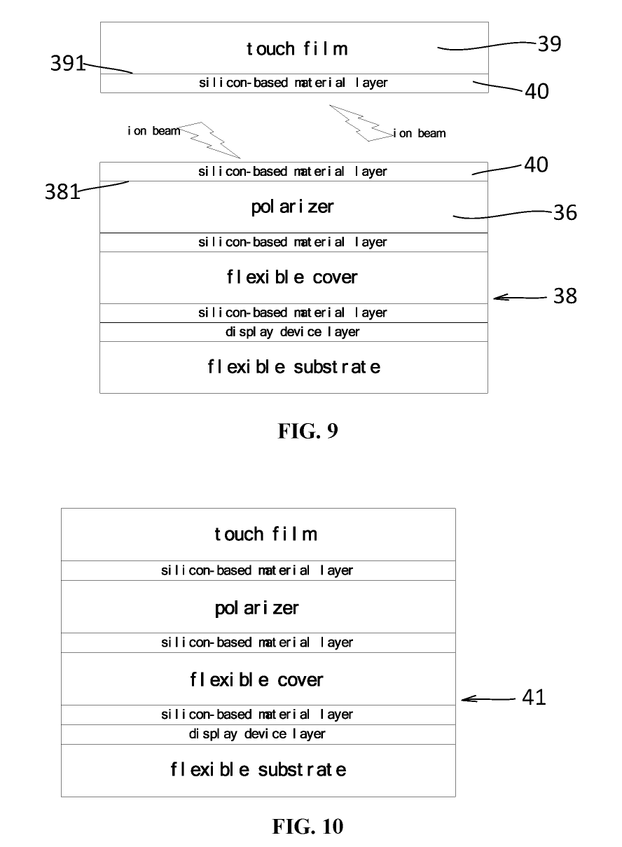

A sixth flexible film (a touch film 39) is bonded to the fifth flexible film 38 to form a seventh flexible film 41. As shown in FIG. 9, in this embodiment, the sixth flexible film is the touch film 39. A lower face of the touch film 39 serves as a sixth packaging face 391. An upper face of the polarizer 36 of the fifth flexible film 38 serves as the fifth packaging face 381.

Specifically, with reference to FIGS. 9 and 10, a silicon-based material layer 40 is disposed on each of the fifth face 381 and the sixth face 391. Then, the silicon-based material layers 40 of the fifth face 381 and the sixth face 391 are shot with ion beams to bond the fifth face 381 and the sixth face 391 together, such that the silicon-based material layers 40 of the fifth face 381 and the sixth face 391 engage with each other. After engagement of the silicon-based material layers 40 of the fifth face 381 and the sixth face 391, the sixth flexible film (the touch film 39) is bonded to the fifth flexible film 38 to form the seventh flexible film 41.

Next, a hard coating 42 is bonded to an upper face of the touch film 39 of the seventh flexible film 41.

The method for manufacturing a multi-layer structure of a flexible display according to the present invention includes the following technical effects. The method uses silicon-based materials to bond the silicon-based material layers 34, 37, 40 of the flexible substrate 31, the flexible cover 33, the polarizer 36, and the touch film 39 together. The thicknesses of the silicon-based materials are much smaller than the thickness of the adhesive used in the conventional technology for bonding films. Thus, the overall thickness of the flexible device produced by the method according to the present invention is smaller. The method for manufacturing a multi-layer structure of a flexible display according to the present invention using silicon-based materials to bond the films of the flexible display together is more reliable than conventional bonding by using adhesives. The flexible films of the flexible display produced by the method according to the present invention are less likely to peel off and are resistant to corrosion by moisture and oxygen.

Thus since the illustrative embodiments disclosed herein may be embodied in other specific forms without departing from the spirit or general characteristics thereof, some of which forms have been indicated, the embodiments described herein are to be considered in all respects illustrative and not restrictive. The scope is to be indicated by the appended claims, rather than by the foregoing description, and all changes which come within the meaning and range of equivalency of the claims are intended to be embraced therein.

1. A method for manufacturing a multi-layer structure, comprising:
providing a first film with a silicon-based material layer thereon;
providing a second film with the silicon-based material layer thereon;
pre-treating the silicon-based material layer on each of the first and second film with an ion beam; and
attaching the first film to the second film through the silicon-based material layer, such that the silicon-based materials layer on the first and second film are disposed between the first film and the second film to form the multi layers structure.

2. The method for manufacturing a multi-layer structure according to claim 1, wherein the silicon-based material layer is made of SiNₓ or SiOₓ.

3. The method for manufacturing a multi-layer structure according to claim 1, wherein the silicon-based material layer is formed by evaporation or magnetron sputtering.

4. The method for manufacturing a multi-layer structure according to claim 1, wherein the ion beam is an argon ion beam.

5. The method for manufacturing a multi-layer structure according to claim 1, wherein the first film includes at least one of a flexible substrate, a display device layer, a flexible cover, a polarizer, and a touch film.

6. The method for manufacturing a multi-layer structure according to claim 1, wherein the second film includes at least one of a flexible substrate, a display device layer, a flexible cover, a polarizer, and a touch film.

7. The method for manufacturing a multi-layer structure according to claim 6, wherein the display device layer includes an organic light emitting diode and a thin film transistor for driving the organic light emitting diode.

8. The method for manufacturing a multi-layer structure according to claim 5, wherein the display device layer includes an organic light emitting diode and a thin film transistor for driving the organic light emitting diode.

9. A flexible display, comprising:
a first film and a second film; and
the first film and the second film are attached by a silicon-based material layer.

10. The flexible display according to claim 9, wherein the silicon-based material layer is made of SiNₓ or SiOₓ.

11. The flexible display according to claim 9, wherein the first film includes at least one of a flexible substrate, a display device layer, a flexible cover, a polarizer, and a touch film.

12. The flexible display according to claim 9, wherein the second film includes at least one of a flexible substrate, a display device layer, a flexible cover, a polarizer, and a touch film.

13. The flexible display according to claim 11, wherein the display device layer includes an organic light emitting diode and a thin film transistor for driving the organic light emitting diode.

14. The flexible display according to claim 12, wherein the display device layer includes an organic light emitting diode and a thin film transistor for driving the organic light emitting diode.
